(19) United States
(12) Patent Application Publication
(10) Pub. No.: US 2022/0404529 A1
(43) Pub. Date: Dec. 22, 2022

(54) WINDOW, ELECTRONIC DEVICE INCLUDING THE WINDOW, AND METHOD FOR MANUFACTURING THE WINDOW

(71) Applicant: Samsung Display Co., Ltd., Yongin-si (KR)

(72) Inventors: YOUNGSANG PARK, Seoul (KR); NAMHEE PARK, Hwaseong-si (KR); HANSOL KANG, Cheonan-si (KR); INSEOK SEO, Asan-si (KR); SANG-IL PARK, Yongin-si (KR); SUNGGUK AN, Suwon-si (KR); JANG DOO LEE, Hwaseong-si (KR)

(21) Appl. No.: 17/717,626

(22) Filed: Apr. 11, 2022

(30) Foreign Application Priority Data
Jun. 16, 2021 (KR) 10-2021-0078102

(51) Int. Cl. G02B 1/18; G02B 1/14; G06F 1/16; B32B 33/00; B32B 27/08; B32B 37/18

(52) U.S. Cl. CPC G02B 1/18; G02B 1/14; G06F 1/1652; B32B 33/00; B32B 27/08; B32B 37/18; B32B 2457/20; B32B 2255/10; B32B 2255/26; B32B 2250/03; B32B 2250/24; B32B 2307/412; B32B 2310/0831; B32B 2307/732

(57) ABSTRACT

A window includes: a base panel, and a protection layer disposed above the base panel. The base panel includes: a first base layer, a second base layer disposed below the first base layer, and a first hard coating layer disposed between the first base layer and the second base layer. The protection layer includes: a base film disposed above the first base layer, and a functional layer disposed above the base film and containing a hard coating agent.

This application claims priority to Korean Patent Application No. 10-2021-0078102, filed on Jun. 16, 2021, and all the benefits accruing therefrom under 35 U.S.C. § 119, the content of which in its entirety is herein incorporated by reference.

### BACKGROUND

The present disclosure herein relates to a window, an electronic device including the window, and a method for manufacturing the window, and more particularly, to a flexible electronic device, a window used therein, and a method for manufacturing the window.

Various types of electronic devices are being used to provide image information, and the electronic devices including flexible display devices that are foldable or bendable have been developed lately. The flexible display devices, unlike rigid display devices, are variously modifiable in shape by being folded, rolled, or bent, and thus have portability without being limited to display screen sizes.

### SUMMARY

Such a flexible display device is desirable to include a window for protecting a display panel without hurting folding or bending operation, and accordingly, there remains a need for developing a window having satisfactory folding characteristics and excellent mechanical properties.

The present disclosure provides a window having excellent impact resistance and surface strength.

The present disclosure also provides an electronic device including a window in which impact resistance due to external impact is improved.

In addition, the present disclosure also provides a method for manufacturing a window in direct contact with a base layer and a hard coating layer.

An embodiment of the present invention provides a window including: a base panel, and a protection layer disposed above the base panel, where the base panel includes: a first base layer, a second base layer disposed below the first base layer, and a first hard coating layer disposed between the first base layer and the second base layer; and the protection layer includes: a base film disposed above the first base layer, and a functional layer disposed above the base film and containing a hard coating agent.

In an embodiment, the window may have a light transmittance of 90 percentages (%) or more and a haze of 1% or less in a visible light range.

In an embodiment, the first base layer may be a polymer film containing polyimide, polyamide, polyethylene terephthalate, polycarbonate, or polyethylene naphthalate.

In an embodiment, the first base layer may have a thickness of about 30 micrometers (μm) to about 100 μm.

In an embodiment, the second base layer may contain polyimide, polyamide, polyethylene terephthalate, polyacrylate, polymethyl methacrylate, polycarbonate, polyethylene naphthalate, polyurethane, polydimethylsiloxane, or rubber.

In an embodiment, the second base layer may have a thickness of about 30 μm to about 200 μm.

In an embodiment, the base panel may further include a second hard coating layer disposed above the first base layer.

In an embodiment, the first hard coating layer and the second hard coating layer may each independently have a thickness of about 5 μm or to about 25 μm.

In an embodiment, the first hard coating layer and the second hard coating layer may each independently contain an acrylic compound, an epoxy-based compound, a siloxane-based compound, or a urethane-based compound.

In an embodiment, the base panel may further include a third base layer disposed above the second hard coating layer, and the third base layer may contain polyimide, polyamide, polyethylene terephthalate, polyacrylate, polymethyl methacrylate, polycarbonate, polyethylene naphthalate, polyurethane, polydimethylsiloxane, or rubber.

In an embodiment, the third base layer may have a thickness of about 30 μm to about 200 μm.

In an embodiment, the first hard coating layer may be directly disposed between the first base layer and the second base layer.

In an embodiment, the functional layer may further include an anti-fingerprint coating agent, and may be a single layer.

In an embodiment, the functional layer may include a first sub-functional layer containing the hard coating agent, and a second sub-functional layer disposed above the first sub-functional layer and containing an anti-fingerprint coating agent.

In an embodiment, the protection layer may further include a third hard coating layer disposed between the base panel and the base film.

In an embodiment, the window may further include a window adhesive layer disposed between the base panel and the protection layer.

In an embodiment of the present invention, an electronic device includes: a display module, and a window disposed above the display module and including a base panel and a protection layer disposed above the base panel. In an embodiment, the base panel includes: a first base layer, a second base layer disposed below the first base layer, and a first hard coating layer disposed between the first base layer and the second base layer. The protection layer includes: a base film disposed above the first base layer, and a functional layer disposed above the base film and containing a hard coating agent.

In an embodiment, the electronic device may be divided into a folding area which is folded with respect to a folding axis extending in one direction and a non-folding area adjacent to the folding area.

In an embodiment, the first base layer may be a polymer film containing polyimide, polyamide, polyethylene terephthalate, polyacrylate, polymethyl methacrylate, polycarbonate, or polyethylene naphthalate, and may have a thickness of about 30 μm to about 100 μm.

In an embodiment, the second base layer may contain polyimide, polyamide, polyethylene terephthalate, polyacrylate, polymethyl methacrylate, polycarbonate, polyethylene naphthalate, polyurethane, polydimethylsiloxane, or rubber, and may have a thickness of about 30 μm to about 200 μm.

In an embodiment, the base panel may further include a second hard coating layer disposed above the first base layer.

In an embodiment, the first hard coating layer and the second hard coating layer may each independently contain an acrylic compound, an epoxy-based compound, a siloxane-based compound, or a urethane-based compound, and may each independently have a thickness of about 5 μm or to about 25 μm.

In an embodiment, the functional layer may be an uppermost layer, and may further include an anti-fingerprint coating agent.

In an embodiment of the present invention, a method for manufacturing a window includes: providing a base panel, and providing a protection layer on the base panel. In an embodiment, the providing of the base panel includes: providing a first base layer, providing a hard coating composition on one surface of the first base layer, providing a second base layer facing the first base layer with the provided hard coating composition therebetween, and irradiating the first base layer, the hard coating composition, and the second base layer, which are stacked, with ultraviolet (“UV”) light to form a first hard coating layer.

In an embodiment, the hard coating composition may contain an acrylic compound, an epoxy-based compound, a siloxane-based compound, or a urethane-based compound.

In an embodiment, the first base layer may be a polymer film containing polyimide, poly amide, polyethylene terephthalate, polyacrylate, polymethyl methacrylate, polycarbonate, or polyethylene naphthalate, and may have a thickness of about 30 μm to about 100 μm.

In an embodiment, the second base layer may contain polyimide, polyamide, polyethylene terephthalate, polyacrylate, polymethyl methacrylate, polycarbonate, polyethylene naphthalate, polyurethane, polydimethylsiloxane, or rubber, and may have a thickness of about 30 μm to about 200 μm.

### BRIEF DESCRIPTION OF THE FIGURES

The accompanying drawings are included to provide a further understanding of the present invention, and are incorporated in and constitute a part of this specification. The drawings illustrate embodiments of the present invention and, together with the description, serve to explain principles of the present invention. In the drawings:

FIG. 1A is a perspective view illustrating an electronic device in an unfolded state according to an embodiment;

FIG. 1B is a perspective view illustrating an in-folding process of the electronic device according to an embodiment shown in FIG. 1A;

FIG. 1C is a perspective view illustrating an out-folding process of the electronic device according to an embodiment shown in FIG. 1A;

FIG. 2A is a perspective view illustrating an electronic device in an unfolded state according to an embodiment;

FIG. 2B is a perspective view illustrating an in-folding process of the electronic device according to an embodiment shown in FIG. 2A;

FIG. 3 is an exploded perspective view of an electronic device according to an embodiment;

FIG. 4 is a cross-sectional view of an electronic device according to an embodiment;

FIG. 5 is a cross-sectional view of a window according to an embodiment;

FIG. 6 is a cross-sectional view of a window according to an embodiment;

FIG. 7A is a cross-sectional view of a base panel according to an embodiment;

FIG. 7B is a cross-sectional view of a base panel according to an embodiment;

FIG. 8A is a cross-sectional view of a protection layer according to an embodiment;

FIG. 8B is a cross-sectional view of a protection layer according to an embodiment;

FIG. 9A is a flowchart of a method for manufacturing a window of an embodiment;

FIG. 9B is a flowchart illustrating a process in a method for manufacturing a window of an embodiment;

FIG. 10A is a view schematically illustrating a process in a method for manufacturing a window of an embodiment; and

FIG. 10B is a view schematically illustrating a process in a method for manufacturing a window of an embodiment.

### DETAILED DESCRIPTION

The present invention may be modified in many alternate forms, and thus specific embodiments will be exemplified in the drawings and described in detail. It should be understood, however, that it is not intended to limit the present invention to the particular forms disclosed, but rather, is intended to cover all modifications, equivalents, and alternatives falling within the spirit and scope of the invention.

In the present description, when an element (or a region, a layer, a portion, etc.) is referred to as being “on,” “connected to,” or “coupled to” another element, it means that the element may be directly disposed on/connected to/coupled to the other element, or that a third element may be disposed therebetween.

In the present description, “directly disposed” may indicate that there is no layer, film, region, plate or the like added between a portion of a layer, a film, a region, a plate or the like and other portions. For example, “directly disposed” may indicate disposing without additional members such as an adhesive member between two layers or two members. Like reference numerals refer to like elements.

Also, in the drawings, the thickness, the ratio, and the dimensions of elements are exaggerated for an effective description of technical contents. The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. For example, “an element” has the same meaning as “at least one element,” unless the context clearly indicates otherwise. “At least one” is not to be construed as limiting “a” or “an.” “Or” means “and/or.” The term “and/or,” includes all combinations of one or more of which associated configurations may define.

It will be understood that, although the terms “first”, “second”, etc. may be used herein to describe various elements, these elements should not be limited by these terms. These terms are only used to distinguish one element from another. For example, a first element could be termed a second element, and, similarly, a second element could be termed a first element, without departing from the scope of example embodiments of the present invention. The terms of a singular form may include plural forms unless the context clearly indicates otherwise.

In addition, terms such as “below,” “lower,” “above,” “upper,” and the like are used to describe the relationship of the configurations shown in the drawings. The terms are used as a relative concept and are described with reference to the direction indicated in the drawings. In the present description, it should be understood that when an element is referred to as “disposed on”, it may be as disposed “above” or “under” the other element.

It should be understood that the terms “comprise”, or “have” are intended to specify the presence of stated features, integers, steps, operations, elements, components, or combinations thereof in the disclosure, but do not preclude the presence or addition of one or more other features, integers, steps, operations, elements, components, or combinations thereof.

Unless otherwise defined, all terms (including technical and scientific terms) used herein have the same meaning as commonly understood by one of ordinary skill in the art to which the present invention pertains. It is also to be understood that terms defined in commonly used dictionaries should be interpreted as having meanings consistent with the meanings in the context of the related art, and are expressly defined herein unless they are interpreted in an ideal or overly formal sense.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within ±30%, 20%, 10% or 5% of the stated value. Hereinafter, a window according to an embodiment of the present invention, an electronic device of an embodiment, and a method for manufacturing a window of an embodiment will be described with reference to the accompanying drawings.

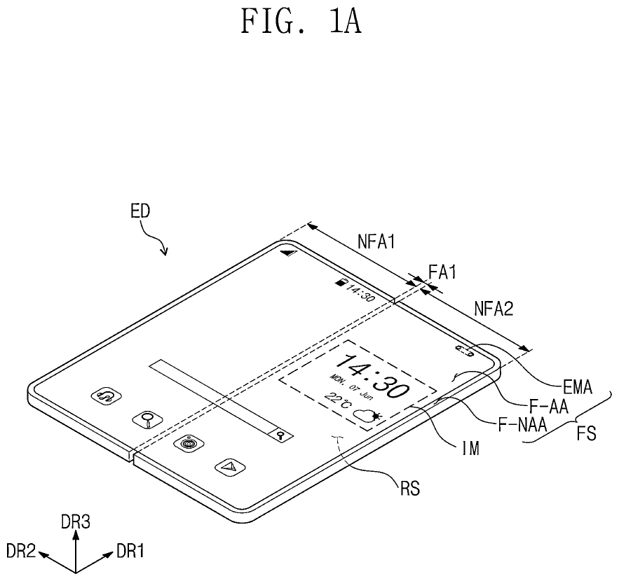

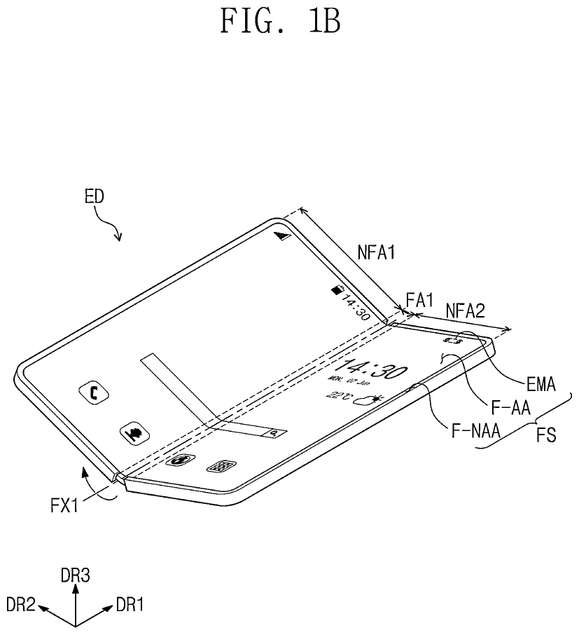

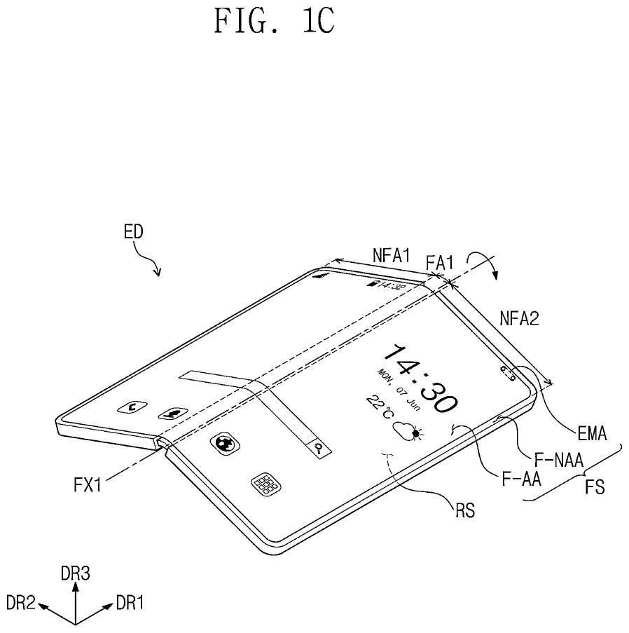

FIG. 1A is a perspective view illustrating an electronic device in an unfolded state according to an embodiment. FIG. 1B is a perspective view illustrating an in-folding process of the electronic device shown in FIG. 1A. FIG. 1C is a perspective view illustrating an out-folding process of the electronic device shown in FIG. 1A.

An electronic device ED may be a device activated according to electrical signals. For example, the electronic device ED may be a mobile phone, a tablet, a car navigation system, a game console, or a wearable device, but the embodiment is not limited thereto. In FIG. 1A, etc. of the present description, as an example, the electronic device ED is shown as a mobile phone.

FIG. 1A and the following drawings illustrate the first to third directional axes DR1 to DR3, and directions indicated by the first to third directional axes DR1, DR2, and DR3 described herein are relative concepts, and may thus be changed to other directions. In addition, the directions indicated by the first to third directional axes DR1, DR2, and DR3 may be described as first to third directions, and the same reference numerals may be used.

Referring to FIGS. 1A to 1C, the electronic device ED according to an embodiment may include a first display surface FS defined by a first directional axis DR1 and a second directional axis DR2 crossing the first directional axis DR1. The electronic device ED may provide an image IM to users through the first display surface FS. The electronic device ED according to an embodiment may display an image IM towards the third directional axis DR3 on the first display surface FS parallel to a first directional axis DR1 and a second directional axis DR2, respectively. In the present description, a front surface (or an upper surface) and a rear surface (or a lower surface) of respective members are defined with respect to a direction in which the image IM is displayed. Front and rear surfaces may oppose each other in a third directional axis DR3 and the normal direction of each of the front and rear surfaces may be parallel to the third directional axis DR3.

The electronic device ED according to an embodiment may include the first display surface FS and a second display surface RS. The first display surface FS may include a first active area F-AA and a first peripheral area F-NAA. The first active area F-AA may include an electronic module area EMA. The second display surface RS may be defined as a surface facing at least a portion of the first display surface FS. That is, the second display surface RS may be defined as a portion of the rear surface of the electronic device ED.

The electronic device ED according to an embodiment may detect external inputs applied from the outside. The external inputs may include various forms of inputs provided from outside the electronic device ED. For example, the external inputs may include external inputs applied when approaching the electronic device ED or being adjacent by a predetermined distance (e.g., hovering), as well as contact by a part of a body such as a user's hand. In addition, the external inputs may have various forms such as force, pressure, temperature, light, etc.

The electronic device ED may include a folding area FA1 and non-folding areas NFA1 and NFA2. The electronic device ED of an embodiment may include a first non-folding area NFA1 and a second non-folding area NFA2 disposed with the folding area FA1 therebetween. FIGS. 1A to 1C illustrate an embodiment of the electronic device ED including one folding area FA1, but the embodiment of the present invention is not limited thereto, and in the electronic device ED, a plurality of folding areas may be defined in another embodiment.

Referring to FIG. 1B, the electronic device ED according to an embodiment may be folded with respect to the first folding axis FX1. The first folding axis FX1 is a virtual axis extending in a direction of the first directional axis DR1, and the first folding axis FX1 may be parallel to a long side direction of the electronic device ED. The first folding axis FX1 may extend along the first directional axis DR1 on the first display surface FS.

In an embodiment, the non-folding areas NFA1 and NFA2 may be disposed adjacent to the folding area FA1 with the folding area FA1 therebetween. For example, the first non-folding area NFA1 may be disposed at one side of the folding area FA1 in the second direction DR2, and the second non-folding area NFA2 may be disposed at the other side of the folding area FA1 in the second direction DR2.

The electronic device ED may be folded with respect to the first folding axis FX1 to become in-folded such that one area overlapping the first non-folding area NFA1 and the other area overlapping the second non-folding area NFA2 on the first display surface FS face each other. In the electronic device ED according to an embodiment, the second display surface RS may be viewed in an in-folded state by users. The second display surface RS may further include an electronic module area in which an electronic module including various components is disposed, and is not limited to any one embodiment.

Referring to FIG. 1C, the electronic device ED may be folded with respect to the first folding axis FX1 to become out-folded such that one area overlapping the first non-folding area NFA1 and the other area overlapping the second non-folding area NFA2 on the second display surface RS face each other. However, the embodiment of the present invention is not limited thereto, and the electronic device ED may be folded with respect to a plurality of folding axes such that portions of each of the first display surface FS and the second display surface RS may face each other, and the number of folding axes and the number of the corresponding non-folding areas are not particularly limited in another embodiment.

The electronic module area EMA may have various electronic modules disposed. For example, the electronic module may include at least any one among a camera, a speaker, a light detection sensor, and a heat detection sensor. The electronic module area EMA may detect an external subject received through the first and second display surfaces FS and RS, or provide sound signals such as voice to the outside through the first and second display surfaces FS and RS. The electronic module may include a plurality of components, and is not limited to any one embodiment.

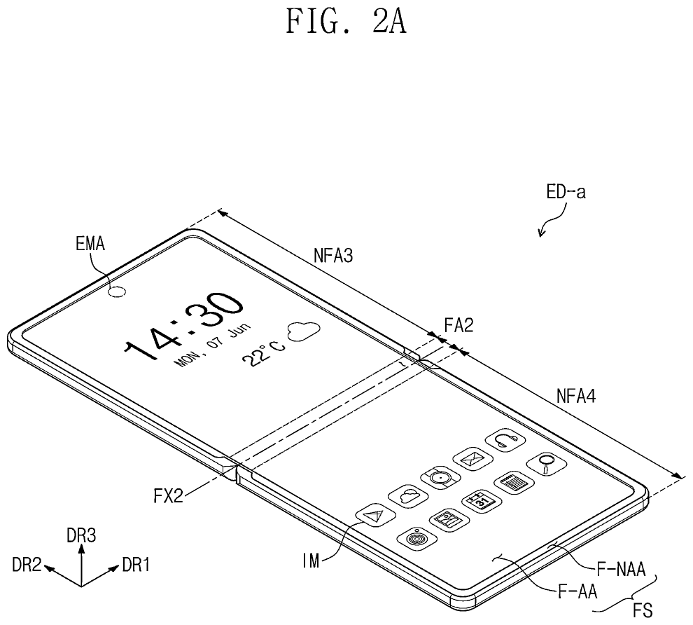

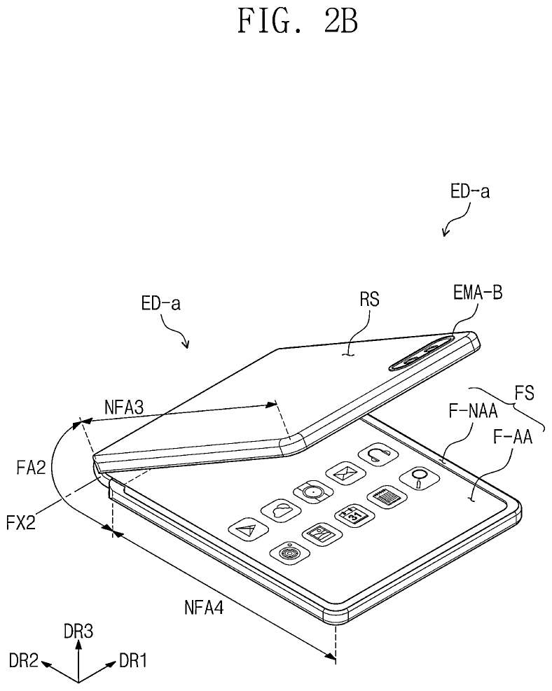

FIG. 2A is a perspective view illustrating an electronic device in an unfolded state according to an embodiment. FIG. 2B is a perspective view illustrating an in-folding process of the electronic device shown in FIG. 2A.

An electronic device ED-a of an embodiment may be folded with respect to a second folding axis FX2 extending in one direction parallel to the first directional axis DR1. FIG. 2B illustrates a case in which a direction that the second folding axis FX2 extends is parallel to a direction that a short side of the electronic device ED-a extends. However, the embodiment of the present invention is not limited thereto.

The electronic device ED-a according to an embodiment may include at least one folding area FA2 and non-folding areas NFA3 and NFA4 adjacent to the folding area FA2. The non-folding areas NFA3 and NFA4 may be disposed to be spaced apart from each other with the folding area FA2 therebetween.

The folding area FA2 has a predetermined curvature and a predetermined radius of curvature. In an embodiment, the first non-folding area NFA3 and the second non-folding area NFA4 face each other, and the electronic device ED-a may be in-folded such that the display surface FS is not exposed to the outside. In addition, unlike what is shown, in an embodiment, the electronic device ED-a may be out-folded such that the display surface FS is exposed to the outside. The electronic device ED-a of an embodiment may include the first display surface FS and the second display surface RS, and the first display surface FS may include an active area F-AA and a peripheral area F-NAA. In addition, the electronic device ED-a may include an electronic module areas EMA and EMA-B.

The electronic devices ED and ED-a of an embodiment described with reference to FIGS. 1A to 2B may be configured such that an in-folding operation or an out-folding operation is alternately repeated from an unfolding operation, but the embodiment is not limited thereto. In another embodiment, the electronic devices ED and ED-a may be configured to select any one of an unfolding operation, an in-folding operation, or an out-folding operation. In addition, although not shown, the electronic device of an embodiment may include a plurality of folding areas, or may be a flexible electronic device in which at least some portions thereof are bendable or rollable.

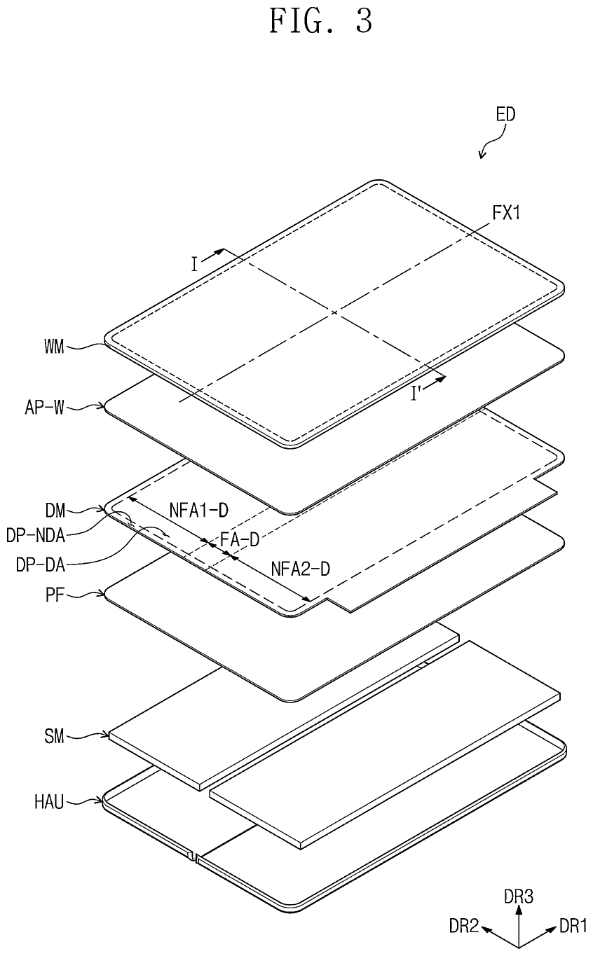

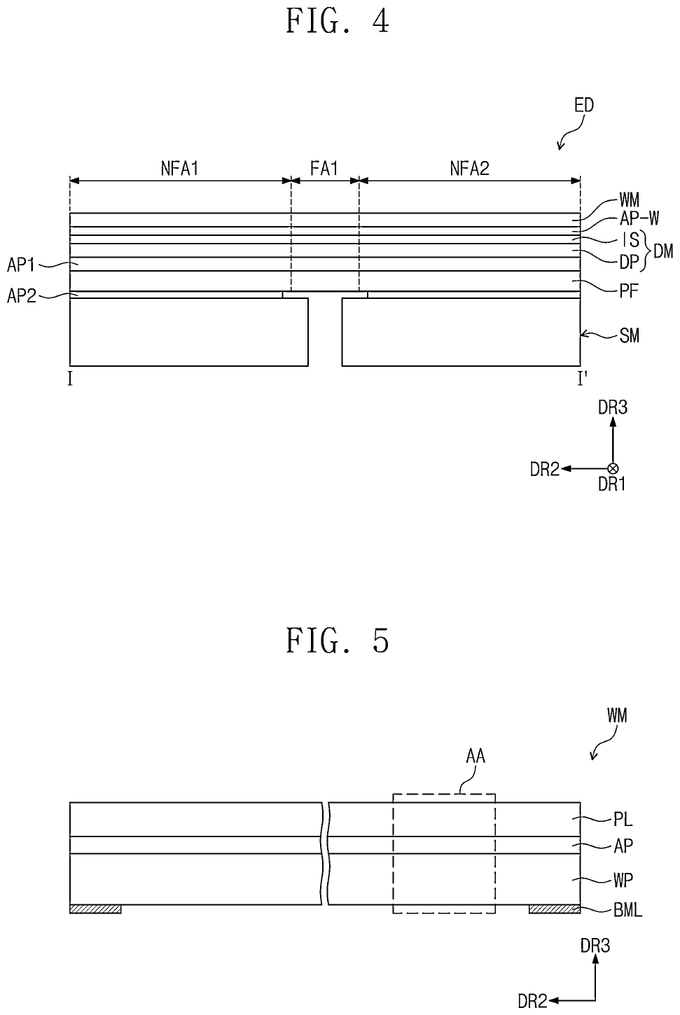

FIG. 3 is an exploded perspective view of an electronic device according to an embodiment, and FIG. 4 is a cross-sectional view of an electronic device according to an embodiment. FIG. 3 illustrates an exploded perspective view of an electronic device according to an embodiment shown in FIG. 1A as an example. FIG. 4 is a cross-sectional view showing a portion corresponding to line I-I′ of FIG. 3.

Referring to FIGS. 3 and 4, the electronic device ED of an embodiment may include a display module DM and a window WM disposed on the display module DM. In addition, the electronic device ED of an embodiment may include an electronic module (not shown) disposed below the display module DM. For example, the electronic module (not shown) may include a camera module. The electronic device ED of an embodiment may include an adhesive layer AP-W disposed between the display module DM and the window WM, a lower module SM disposed below the display module DM, and a support layer PF.

The window WM may cover the entire upper surface of the display module DM. The window WM may have a shape corresponding to the shape of the display module DM. The window WM may have flexibility that is deformed according to the folding or bending operation of the electronic device ED. In addition, the window WM may serve to protect the display module DM from external impacts.

The electronic device ED of an embodiment may include a housing HAU accommodating the display module DM, the lower module SM, etc. The housing HAU may be combined with the window WM. Although not shown, the housing HAU may further include a hinge structure to make folding or bending easy.

In the electronic device ED of an embodiment, the adhesive layer AP-W disposed between the window WM and the display module DM may be an optically clear adhesive film (“OCA”) or an optically clear adhesive resin layer (“OCR”). In an embodiment, the adhesive layer AP-W may be omitted.

The display module DM may display images according to electrical signals and transmit/receive information on external inputs. The display module DM may include a display area DP-DA and a non-display area DP-NDA. The display area DP-DA may be defined as an area outputting images provided from the display module DM.

The display module DM may include a display panel DP, and an input sensor IS disposed on the display panel DP. The display panel DP may include a display element layer. For example, the display element layer may include an organic electroluminescence element, a quantum dot light emitting element, or a liquid crystal element layer. However, the embodiment of the present invention is not limited thereto.

The input sensor IS may include a plurality of sensing electrodes for detecting external inputs. The input sensor IS may be a capacitance sensor, but is not particularly limited thereto. The input sensor IS may be directly formed on the display panel DP through a continuous process when the display panel DP is manufactured. However, the embodiment of the present invention is not limited thereto, and the input sensor IS may be manufactured as a separate panel from the display panel DP, and be attached to the display panel DP through an adhesive layer (not shown) in another embodiment.

In the electronic device ED according to an embodiment, the display module DM may include a folding display portion FA-D and non-folding display portions NFA1-D and NFA2-D. The folding display portion FA-D may be a portion corresponding to the folding area FA1 (FIG. 1A), and the non-folding display portions NFA1-D and NFA2-D may be portions corresponding to the non-folding areas NFA1 and NFA2 (FIG. 1A).

The window WM according to an embodiment is disposed on the display module DM. The window WM may include an optically transparent insulating material. The window WM may protect the display panel DP and the input sensor IS. The image IM (FIG. 1A) generated from the display panel DP may be provided to users by being transmitted through the window WM. The window WM may provide a touch surface of the electronic device ED. In the electronic device ED including the folding area FA1, the window WM may be a flexible window which is foldable or bendable.

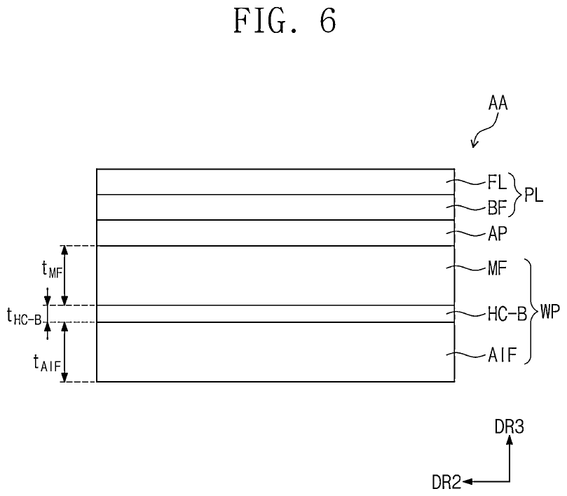

The window WM may include a base panel WP including a first base layer MF (FIG. 6) of a polymer material as a base substrate, and a protection layer PL (FIG. 6) disposed on the base panel WP. The window WM according to an embodiment will be described in more detail later.

In the electronic device ED according to an embodiment, the lower module SM may include at least one of a support plate, a cushion layer, a shielding layer, a filling layer, or an interlayer bonding layer. The lower module SM may support the display module DM or may prevent the display module DM from being deformed due to an external impact or force.

The support plate may be formed of or include a metal material or a polymer material. The cushion layer may include sponge, foam, or elastomer such as a urethane resin. The shielding layer may be an electromagnetic wave shielding layer or a heat dissipation layer. In addition, the shielding layer may serve as an adhesive layer. The interlayer bonding layer may be provided in the form of an adhesive resin layer or an adhesive tape. The filling layer may fill a space between the support layer PF and the housing HAU, and fix the support layer PF.

The support layer PF may be a layer disposed below the display module DM to protect a rear surface of the display module DM. The support layer PF may overlap the entire display module DM. The support layer PF may include a plastic material. For example, the support layer PF may be a polyimide (“PI”) film or a polyethylene terephthalate (“PET”) film. However, this is presented as an example, and the material of the support layer PF is not limited thereto.

In addition, the electronic device ED of an embodiment may further include at least one adhesive layer AP1 or AP2. For example, the first adhesive layer AP1 may be disposed between the display module DM and the support layer PF and the second adhesive layer AP2 may be disposed between the support layer PF and the lower module SM. The at least one adhesive layer AP1 or AP2 may be an optically clear adhesive film (OCA) or an optically clear adhesive resin layer (OCR).

FIG. 5 is a cross-sectional view showing a window according to an embodiment. FIG. 6 is a cross-sectional view showing a portion of a window according to an embodiment. FIG. 6 is a cross-sectional view showing area AA of FIG. 5.

The window WM of an embodiment may include a base panel WP and a protection layer PL disposed above the base panel WP. A window adhesive layer AP may be disposed between the base panel WP and the protection layer PL. The window WM may be included in the electronic device described with reference to FIGS. 1A to 4. That is, the window WM of an embodiment has flexibility enabling folding or bending, and may protect the display module DM (FIG. 4) disposed below from external impacts and scratches.

The window WM included in the electronic device ED (FIG. 4) may exhibit excellent optical properties. The window WM may exhibit a light transmittance of 90 percentages (%) or more in a wavelength range of about 380 nanometers (nm) to about 780 nm, which is a visible light range. In addition, the window WM may have a haze value of 1% or less. That is, the window WM of an embodiment provided by stacking the base panel WP and the protection layer PL has optical properties of a light transmittance of 90% or more and a haze of 1% or less in the visible light range, and thus enables an electronic device to have excellent display quality.

The window WM may include a printing layer BML. The printing layer BML may be disposed on one surface of the base panel WP. In an embodiment, the printing layer BML may be provided on a lower surface of the base panel WP adjacent to the display module DM (FIG. 4). The printing layer BML may be disposed on an edge area of the base panel WP. The printing layer BML may be an ink printing layer. Further, the printing layer BML may be a layer formed by including a pigment or dye. In the base panel WP, the printing layer BML may be a portion corresponding to the non-display area DP-NDA (FIG. 3) of the display module DM.

The protection layer PL is disposed above the base panel WP and may be an uppermost layer of the electronic devices ED and ED-a (FIGS. 1A and 2A). The protection layer PL is a layer exposed to the outermost surface of the electronic devices ED and ED-a (FIGS. 1A and 2A), and may serve to protect the base panel WP, the display module DM, and the like.

The window adhesive layer AP may bond the base panel WP and the protection layer PL together. The window adhesive layer AP may be an optically clear adhesive film (OCA) or an optically clear adhesive resin layer (OCR).

The window WM including the base panel WP, the window adhesive layer AP, and the protection layer PL has optical properties of a light transmittance of 90% or more and a haze of 1% or less in the visible light range, and also does not show buckling during folding or bending, and thus an electronic device including the window of an embodiment may exhibit excellent display quality.

FIG. 6 is a cross-sectional view showing a window of an embodiment. FIG. 6 is a cross-sectional view showing area AA of FIG. 5.

In the window of an embodiment, the base panel WP may include a first base layer MF, a second base layer AIF, and a first hard coating layer HC-B disposed between the first base layer MF and the second base layer AIF. The second base layer AIF is disposed below the first base layer MF, and may be a layer adjacent to the display module DM (FIG. 4).

The first base layer MF may correspond to a support member provided with the hard coating layer HC-B and the like in the base panel WP. The first base layer MF may be formed of or include a polymer material. The first base layer MF may be a flexible polymer film. The first base layer MF may be made of polyimide (PI), polyamide (PA)), polyethylene terephthalate (PET), polyacrylate, polymethylmethacrylate (PMMA), polycarbonate (PC), or polyethylene naphthalate (PEN), or a combination thereof. For example, the first base layer MF may be a polyimide film or a polyethylene terephthalate film. However, the first base layer MF of the base panel WP used in an embodiment is not limited to the presented polymer materials, and any material having optical transparency, which provides users with images provided from the display module DM (FIG. 4) and having flexibility that does not affect the folding and bending characteristics of the display module may be used without limitation.

The first base layer MF may have a thickness t_{MF} of about 30 micrometers (μm) to about 100 μm. For example, the first base layer MF may have a thickness t_{MF} of about 30 μm to about 50 μm. When the first base layer MF has a thickness t_{MF} of less than 30 μm, the window WM may have reduced durability. In addition, when the first base layer MF has a thickness t_{MF} of greater than 100 μm, the thickness of the window WM increases, which may not be suitable for obtaining a thin electronic device or a foldable electronic device.

In addition, in the window WM of an embodiment, the first base layer MF included in the base panel WP may be provided in a form that a plurality of polymer films are stacked. In the first base layer MF in which a plurality of polymer films are stacked, the polymer films include the same type of polymer material and separated films having different thicknesses may be stacked, or a plurality of polymer films may be formed of different polymer materials.

The first base layer MF may have a modulus of about 3.5 gigapascals (GPa) to about 9.0 GPa. The first base layer MF has a modulus of about 3.5 GPa to about 9.0 GPa, and may thus exhibit excellent mechanical properties for protecting the display module. In the present description, the modulus value may be measured through the standard measurement method of ASTM D 638-03.

In the window according to an embodiment, the base panel WP may include the second base layer AIF disposed below the first base layer MF. The base panel WP includes the second base layer AIF, and may thus have improved impact resistance, and the window including the second base layer AIF may prevent the display module from being scratched due to external impact.

The second base layer AIF may be formed of or include a polymer material or a flexible organic material. The second base layer AIF may be made of polyimide (PI), polyamide (“PA”), polyethylene terephthalate (PET), polyacrylate, polymethyl methacrylate (“PMMA”), polycarbonate (“PC”), polyethylene naphthalate (“PEN”), polyurethane (“PU”), polydimethylsiloxane (“PDMS”), rubber, or a combination thereof. For example, the second base layer AIF may be a polyimide film or a polyethylene terephthalate film. Alternatively, the second base layer AIF may be a film including polyurethane, polydimethylsiloxane, or rubber. However, the second base layer AIF of the base panel WP used in an embodiment is not limited to the presented polymer materials or organic materials, and any material having optical transparency, which provides users with images provided from the display module and having flexibility that does not affect the folding and bending characteristics of the display module may be used without limitation.

The second base layer AIF may have a thickness t_{AIF} of about 30 μm to about 200 μm. For example, the second base layer AIF may have a thickness t_{AIF} of about 30 μm to about 50 μm. When the second base layer AIF has a thickness t_{AIF} of less than 30 μm, the window WM may have reduced durability. In addition, when the second base layer AIF has a thickness t_{AIF} of greater than 200 μm, the thickness of the window WM increases, which may not be suitable for obtaining a thin electronic device or a foldable electronic device.

In addition, in the window WM of an embodiment, the second base layer AIF included in the base panel WP may be provided in a form in which a plurality of films are stacked. In the second base layer AIF in which a plurality of films are stacked, the stacked films include the same type of polymer material or organic material, and separated films having different thicknesses may be stacked, or a plurality of films may be formed of different materials.

The second base layer AIF may be a polymer film such as a polyimide film or a polyethylene terephthalate film, and may have a modulus of about 3.5 GPa to about 7.0 GPa. The second base layer AIF in the form of a polymer film has a modulus of about 3.5 GPa to about 7.0 GPa, and may thus exhibit excellent mechanical properties for protecting the display module. In addition, the second base layer AIF in the form of a polymer film may have a thickness t_{AIF} of about 30 μm to about 100 μm.

The second base layer AIF may be a flexible film including polyurethane, polydimethylsiloxane, or rubber, and may have a modulus of about 50 MPa to about 500 MPa. The second base layer AIF including polyurethane, polydimethylsiloxane, rubber, or the like has a modulus of about 50 MPa to about 500 MPa, and may thus exhibit excellent mechanical properties for protecting the display module. In addition, the second base layer AIF including polyurethane, polydimethylsiloxane, rubber, or the like may have a thickness t_{AIF} of about 30 μm to about 200 μm.

In the window WM of an embodiment, the first base layer MF and the second base layer AIF may be formed of the same material or may be formed of different materials. In addition, the first base layer MF and the second base layer AIF disposed to face each other with the first hard coating layer HC-B therebetween may be symmetrical. For example, the first base layer MF and the second base layer AIF may be formed of the same material and have the same thickness. In addition, the first base layer MF and the second base layer AIF may have similar modulus values.

The embodiment of the present invention is not limited thereto, and the first base layer MF and the second base layer AIF may not be symmetrical in another embodiment. The first base layer MF and the second base layer AIF may be provided with a combination of materials and thicknesses to minimize buckling in the window of an embodiment.

The base panel WP according to an embodiment may include a first base layer MF, a second base layer AIF, and a first hard coating layer HC-B disposed between the first base layer MF and the second base layer AIF. The window of an embodiment includes the first hard coating layer HC-B, and may thus exhibit effectively improved durability. In an embodiment, the base panel WP includes the first hard coating layer HC-B disposed between the first base layer MF and the second base layer AIF to disperse impact provided to the window in a vertical direction, and may thus protect the display module disposed below the window from external impact and minimize scratches on the display module.

The first hard coating layer HC-B may be directly disposed on an upper surface of the second base layer AIF. The first hard coating layer HC-B may be directly disposed between the first base layer MF and the second base layer AIF. That is, one surface of the first hard coating layer HC-B may be in contact with a lower surface of the first base layer MF, and the other surface of the first hard coating layer HC-B may be in contact with the upper surface of the second base layer AIF. The first hard coating layer HC-B increases the hardness and impact resistance of the base panel WP, and also serves as a bonding layer for bonding the first base layer MF and the second base layer AIF together.

The hard coating layer HC-B may be formed from a hard coating composition including at least one of an organic-based composition, an inorganic-based composition, or an organic-inorganic composite composition. The first hard coating layer HC-B may be formed of or include an acrylic compound, an epoxy-based compound, a siloxane-based compound, a urethane-based compound, or a combination thereof.

The first hard coating layer HC-B may have a thickness t_{HC-B} of about 5 μm to about 25 μm. For example, the first hard coating layer HC-B may have a thickness t_{HC-B} of about 5 μm to about 10 μm. When the first hard coating layer HC-B has a thickness t_{HC-B} of less than 5 μm, the first hard coating layer HC-B becomes less capable of protecting the first base layer MF and the second base layer AIF, which may cause reduction in durability of a window. In addition, when the first hard coating layer HC-B has a thickness t_{HC-B} of less than 5 μm, the first hard coating layer HC-B may fail to have sufficient surface hardness for protecting the display module DM (FIG. 4). When the first hard coating layer HC-B has a thickness t_{HC-B} of greater than 25 μm, the thickness of a window increases, which may not be suitable for obtaining a thin electronic device or a foldable electronic device.

The first hard coating layer HC-B may have a modulus of about 3.0 GPa to about 5.0 GPa. The first hard coating layer HC-B has a modulus of about 3.0 GPa to about 5.0 GPa, and may allow the window WM to have good flexibility and excellent durability. The first hard coating layer HC-B may have an indentation hardness of 50 Vickers hardness (Hv) or more. The indentation hardness was determined as a point at which a surface of a sample was permanently deformed when a material is strongly pressed with an indentation hardness tester.

The window of an embodiment is disposed on the base panel WP and may include a protection layer PL including a base film BF and a functional layer FL. The functional layer FL is disposed above the base film BF, and the functional layer FL may be an uppermost layer of the window WM.

The base film BF may correspond to a support member provided with the functional layer FL in the protection layer PL. The base film BF may be formed of or include a polymer material. The base film BF may be a flexible polymer film. The base film BF may be made of polyimide (PI), polyamide (PA)), polyethylene terephthalate (PET), polyacrylate, polymethylmethacrylate (PMMA), polycarbonate (PC), or polyethylene naphthalate (PEN), or a combination thereof. For example, the base film BF may be a polyimide film or a polyethylene terephthalate film. However, the base film BF of the protection layer PL used in an embodiment is not limited to the presented polymer materials, and any material having optical transparency, which provides users with images provided from the display module and having flexibility that does not affect the folding and bending characteristics of the display module may be used without limitation.

The functional layer FL may be provided as a single layer or a plurality of layers. The functional layer AF may serve as an anti-fingerprint layer, a hard coating layer, an antistatic layer, or an anti-pollution layer.

In an embodiment, the functional layer FL may include a hard coating agent. In an embodiment shown in FIG. 6, the protection layer PL may include a single layered functional layer FL disposed on the base film BF.

The functional layer FL may include a hard coating agent to serve as a hard coating layer. The hard coating agent included in the functional layer FL may be formed from a hard coating composition including at least one of an organic-based composition, an inorganic-based composition, or an organic-inorganic composite composition. The functional layer FL may contain an acrylic compound, an epoxy-based compound, a siloxane-based compound, or a urethane-based compound as a hard coating agent.

In addition, the functional layer FL may further include an anti-fingerprint coating agent. The anti-fingerprint coating agent may include a fluorine-containing compound. The functional layer FL provided as a single layer may include both a hard coating agent and an anti-fingerprint coating agent. That is, in the window of an embodiment, the functional layer FL may serve both as a hard coating layer and an anti-fingerprint coating layer. In addition, the functional layer FL may further include an anti-reflection agent or an anti-glare agent.

The window of an embodiment includes a base panel including two base layers and a hard coating layer, and a protection layer disposed on the base panel and having a functional layer including a base film and a hard coating agent, and may thus have excellent durability. The window of an embodiment has excellent impact resistance and high surface hardness, and accordingly, the window of an embodiment may effectively protect the display module from external shocks or external stimuli while keeping display quality of an electronic device. In addition, the window of an embodiment includes a flexible base panel and a protection layer, and may thus be used in an electronic device capable of folding or non-folding operation, and the window of an embodiment may effectively improve the durability of an electronic device.

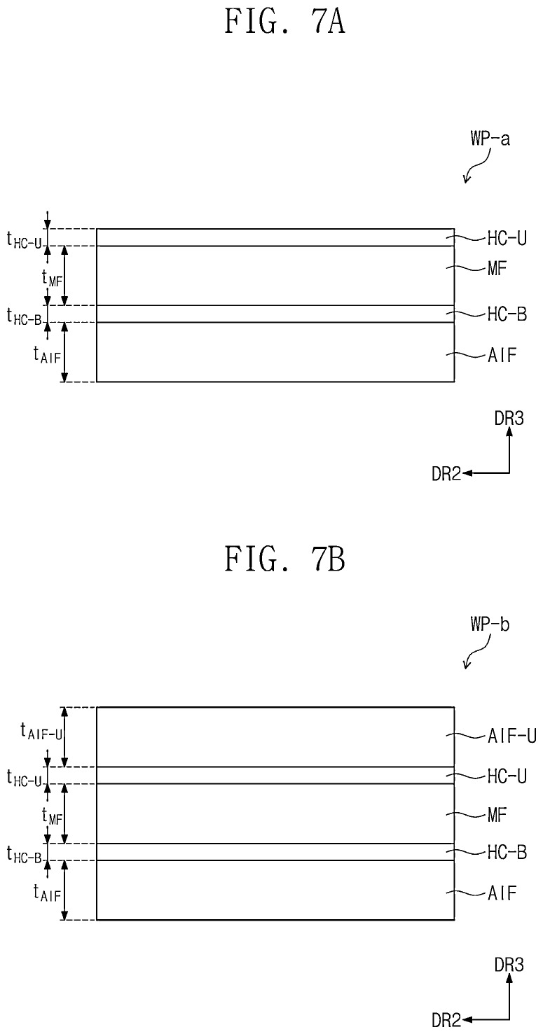

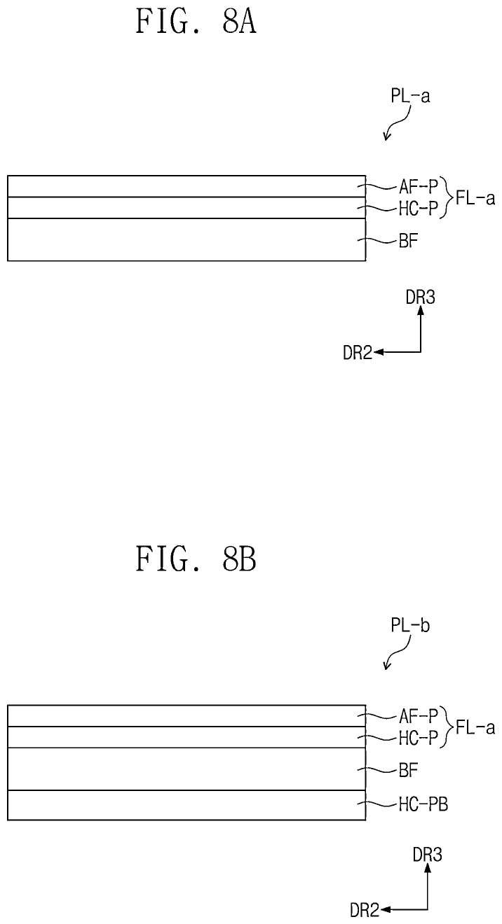

FIGS. 7A and 7B each are cross-sectional views showing a base panel according to an embodiment. FIGS. 8A and 8B each are cross-sectional views showing a protection layer according to an embodiment. In the description of FIGS. 7A and 8B, duplicated descriptions as those described with reference to FIGS. 1 to 6 above will not be described again, and different features will be mainly described.

Referring to FIG. 7A, a base panel WP-a of an embodiment included in the window of an embodiment may further include a second hard coating layer HC-U, unlike the base panel WP shown in FIG. 6. The second hard coating layer HC-U may be disposed above the first base layer MF. The second hard coating layer HC-U may be disposed between the first base layer MF and the protection layer PL (FIG. 6). For example, the second hard coating layer HC-U may be disposed between the first base layer MF and the window adhesive layer AP.

That is, the window of an embodiment may include the base panel WP-a, the window adhesive layer AP (FIG. 6), and the protection layer PL (FIG. 6), which are sequentially stacked. The base panel WP-a according to an embodiment may include the second base layer AIF, the first hard coating layer HC-B, the first base layer MF, and the second hard coating layer HC-U, which are sequentially stacked in the third directional axis DR3 direction, which is the thickness direction. The first hard coating layer HC-B and the second hard coating layer HC-U disposed on the lower surface and the upper surface of the first base layer MF, respectively, may be formed of the same material or different materials.

The first hard coating layer HC-B and the second hard coating layer HC-U may include a hard coating agent having a high hardness. For example, the first hard coating layer HC-B and the second hard coating layer HC-U may be high hardness hard coating layers formed including an acrylic compound, an epoxy-based compound, or a siloxane-based compound.

In addition, in an embodiment, the first hard coating layer HC-B and the second hard coating layer HC-U may include a hard coating agent having a high elasticity. For example, the first hard coating layer HC-B and the second hard coating layer HC-U may be high elastic hard coating layers formed including a urethane-based compound or the like.

In the base panel WP-a of an embodiment, the second hard coating layer HC-U may have a thickness t_{HC-U} of about 5 μm to about 25 μm. For example, the second hard coating layer HC-U may have a thickness t_{HC-U} of about 5 μm to about 10 μm. When the second hard coating layer HC-U has a thickness t_{HC-U} of less than 5 μm, the second hard coating layer HC-U becomes less capable of protecting the first base layer MF and the second base layer AIF, which may cause reduction in durability of a window. In addition, when the second hard coating layer HC-U has a thickness t_{HC-U} of less than 5 μm, the second hard coating layer HC-U may fail to have sufficient surface hardness for protecting the display module DM (FIG. 4). In addition, when the second hard coating layer HC-U has a thickness t_{HC-U} of greater than 25 μm, the thickness of a window increases, which may not be suitable for obtaining a thin electronic device or a foldable electronic device.

The second hard coating layer HC-U may have a modulus of about 3.0 GPa to about 5.0 GPa. The second hard coating layer HC-U has a modulus of about 3.0 GPa to about 5.0 GPa, and may allow the window WM to have good flexibility and excellent durability. The second hard coating layer HC-U may have an indentation hardness of 50 Hv or more.

In the window of an embodiment, the first hard coating layer HC-B and the second hard coating layer HC-U may be symmetrical with the first base layer MF therebetween. For example, the first hard coating layer HC-B and the second hard coating layer HC-U may be formed of the same material, and the first hard coating layer HC-B and the second hard coating layer HC-U may have the same thickness. However, the embodiment is not limited thereto, and the first hard coating layer HC-B and the second hard coating layer HC-U may be provided with different materials in another embodiment.

The window of an embodiment includes the hard coating layers HC-B and HC-U respectively disposed on the lower surface and the upper surface of the first base layer MF, and the second base layer AIF disposed below the first base layer MF, and may thus have excellent impact resistance and durability.

Referring to FIG. 7B, the base panel WP-b of an embodiment included in the window of an embodiment may further include a third base layer AIF-U, unlike the base panel WP-a shown in FIG. 7A. The third base layer AIF-U may be disposed above the second hard coating layer HC-U. The third base layer AIF-U may be disposed between the second hard coating layer HC-U and the protection layer PL (FIG. 6). For example, the third base layer AIF-U may be disposed between the second hard coating layer HC-U and the window adhesive layer AP.

That is, the window of an embodiment may include the base panel WP-b, the window adhesive layer AP (FIG. 6), and the protection layer PL (FIG. 6), which are sequentially stacked. The base panel WP-b according to an embodiment may include the second base layer AIF, the first hard coating layer HC-B, the first base layer MF, the second hard coating layer HC-U, and the third base layer AIF-U which are sequentially stacked in the third directional axis DR3 direction, which is the thickness direction.

The third base layer AIF-U may be formed of or include a polymer material or a flexible organic material. The third base layer AIF-U may be made of polyimide (PI), polyamide (PA), polyethylene terephthalate (PET), polyacrylate, polymethyl methacrylate (PMMA), polycarbonate (PC), polyethylene naphthalate (PEN), polyurethane (PU), polydimethylsiloxane (PDMS), rubber, or a combination thereof. For example, the third base layer AIF-U may be a polyimide film or a polyethylene terephthalate film. Alternatively, the third base layer AIF-U may be a film including polyurethane, polydimethylsiloxane, or rubber. However, the third base layer AIF-U of the base panel WP-b used in an embodiment is not limited to the presented polymer materials or organic materials, and any material having optical transparency, which provides users with images provided from the display module and having flexibility that does not affect the folding and bending characteristics of the display module may be used without limitation.

The third base layer AIF-U may have a thickness t_{AIF-U} of about 30 μm to about 200 μm. For example, the third base layer AIF-U may have a thickness t_{AIF-U} of about 30 μm to about 50 μm. When the third base layer AIF-U has a thickness t_{AIF-U} of less than 30 μm, the window WM may have reduced durability. In addition, when the third base layer AIF-U has a thickness t_{AIF-U} of greater than 200 μm, the thickness of a window increases, which may not be suitable for obtaining a thin electronic device or a foldable electronic device.

In addition, the third base layer AIF-U included in the base panel WP-b according to an embodiment may be a polymer film such as a polyimide film or a polyethylene terephthalate film, and the third base layer AIF-U may have a modulus of about 3.5 GPa to about 7.0 GPa. The third base layer AIF-U in the form of a polymer film has a modulus of about 3.5 GPa to about 7.0 GPa, and may thus exhibit excellent mechanical properties for protecting the display module. In addition, the third base layer AIF-U in the form of a polymer film may have a thickness t_{AIF-U} of about 30 μm to about 100 μm.

The third base layer AIF-U may be a flexible film including polyurethane, polydimethylsiloxane, or rubber, and may have a modulus of about 50 MPa to about 500 MPa. The third base layer AIF-U including polyurethane, polydimethylsiloxane, rubber, or the like has a modulus of about 50 MPa to about 500 MPa, and may thus exhibit excellent mechanical properties for protecting the display module. In addition, the third base layer AIF-U including polyurethane, polydimethylsiloxane, rubber, or the like may have a thickness t_{AIF-U} of about 30 μm to about 200 μm.

In the window of an embodiment, the second base layer AIF and the third base layer AIF-U may be formed of the same material or may be formed of different materials. In addition, the second base layer AIF and the third base layer AIF-U disposed to face each other with the first base layer MF therebetween may be symmetrical. For example, the second base layer AIF and the third base layer AIF-U may be formed of the same material and have the same thickness. In addition, the second base layer AIF and the third base layer AIF-U may have similar modulus values. The embodiment of the present invention is not limited thereto, and the second base layer AIF and the third base layer AIF-U may not be symmetrical in another embodiment. The second base layer AIF and the third base layer AIF-U may be provided with a combination of materials and thicknesses to minimize buckling in the window of an embodiment.

The window of an embodiment includes the hard coating layers HC-B and HC-U disposed on the lower surface and the upper surface of the first base layer MF, respectively, and the second base layer AIF and the third base layer AIF-U disposed below and above the first base layer MF, respectively, and may thus have excellent impact resistance and durability.

Referring to FIG. 8A, the protection layer PL-a of an embodiment included in the window of an embodiment may include a plurality of functional layers, unlike the protection layer PL shown in FIG. 6. The protection layer PL-a according to an embodiment may include the first sub-functional layer HC-P disposed on the base film BF and the second sub-functional layer AF-P disposed above the first sub-functional layer HC-P. The first sub-functional layer HC-P may include a hard coating agent, and the second sub-functional layer AF-P may include an anti-fingerprint coating agent. The first sub-functional layer HC-P may include a hard coating agent containing an acrylic compound, an epoxy-based compound, a siloxane-based compound, or a urethane-based compound. In addition, the second sub-functional layer AF-P may include an anti-fingerprint coating agent containing a fluorine-containing compound.

The protection layer PL-a according to an embodiment shown in FIG. 8A may be disposed on the base panels WP, WP-a, and WP-b shown in FIGS. 6 to 7B. The window according to an embodiment including the protection layer PL-a according to an embodiment may exhibit excellent impact resistance and high surface hardness characteristics.

Referring to FIG. 8B, the protection layer PL-b of an embodiment included in the window of an embodiment may further include a third hard coating layer HC-PB, unlike the protection layer PL-a shown in FIG. 8A. The protection layer PL-a according to an embodiment may include the first sub-functional layer HC-P disposed on the base film BF, the second sub-functional layer AF-P disposed above the first sub-functional layer HC-P, and the third hard coating layer HC-PB disposed below the base film BF.

The third hard coating layer HC-PB may be formed from a hard coating composition including at least one of an organic-based composition, an inorganic-based composition, or an organic-inorganic composite composition. The third hard coating layer HC-PB may be formed of or include an acrylic compound, an epoxy-based compound, a siloxane-based compound, a urethane-based compound, or a combination thereof.

The protection layer PL-b according to an embodiment shown in FIG. 8B may be disposed on the base panels WP, WP-a, and WP-b shown in FIGS. 6 to 7B. The window according to an embodiment including the protection layer PL-b according to an embodiment may exhibit excellent impact resistance and high surface hardness characteristics.

In addition, the protection layer according to an embodiment may include a single layered functional layer disposed on the base film BF, and the third hard coating layer HC-PB disposed below the base film BF.

Although not shown, the window of an embodiment may have a stack structure derived from the combination of the base panel and the protection layer shown in FIGS. 6 to 8B, and the like.

The window of an embodiment including a base panel and a protection layer includes a base panel and a protection layer, and the base panel includes a plurality of base layers and a hard coating layer to exhibit minimized buckling, excellent impact resistance, and high surface hardness characteristics when included in a foldable electronic device.

In Tables 1 and 2 below, the physical properties of windows of Comparative Examples and Examples are compared and shown. Both Comparative Examples and Examples correspond to windows in which a base panel and a protection layer are stacked, and correspond to windows including a window adhesive layer between the base panel and the protection layer. The windows of Comparative Examples and Examples are the same in components of the protection layer including a base film and a functional layer, and are different in components of the base panel.

Table 1 shows components of windows of Comparative Examples and Examples. In the window of an embodiment in Table 1, the base panel has the stack structure shown in FIG. 7A.

TABLE 1

| | Stack structure of | Stack structure of |
|---|---|---|
| Item | protection layer | base panel |
| Comparative | Base film (50 μm)/ | Base layer (50 μm)/ |
| Example | functional layer (5 μm) | Hard coating layer (5 μm) |
| Example | Base film (50 μm)/ | Second base layer (30 μm)/ |
| | functional layer (5 μm) | first hard coating layer |
| | | (25 μm)/first base layer |
| | | (30 μm)/second hard coating |
| | | layer (25 μm) |

Table 2 shows evaluation of optical properties and mechanical properties of Comparative Examples and Examples. In Table 2, light transmittance, reflectance, and yellow index were measured using CM-3600d (KONICA MINOLTA). light transmittance, reflectance, and yellow index were measured at a 2° viewing angle, using A D65 light source. Haze was measured using a D65 light source with NDH200 (NIPPON DENSHOKU). In Table 2, crack strain indicates a level of increase in the size of a sample after extension for an initial test sample when extending test samples. The test sample for crack strain measurement was prepared by laser cutting the sample into a size of 1.0 centimeters (cm)×10 cm. An extension rate was set to 10 millimeters per minute (mm/min), and after the extension was applied, the presence of cracks was checked using a microscope, and an increase in the sample size at the point was evaluated.

Indentation hardness is a value measured using an indentation hardness tester. A load of 30 millinewtons (mN) was applied to a sample at a loading and unloading rate of 30 s to perform measurement. Values measured for indentation hardness is Vickers Hardness (Hv) values. Pencil hardness was measured at a load of 1 kg using a pencil hardness tester.

Impact resistance was evaluated using a pen drop test. Impact resistance was evaluated by dropping a pen having a certain weight onto an upper surface of the window, and measuring a height (cm) at which the upper surface of the window is damaged. The pen used in the impact resistance test had a diameter of 0.7 millimeters (mm) in one end, and a tungsten carbide-based pen without a spring was used. The pen was used without a spring and weighed about 5.81 grams (g).

In Table 2, the item of steel wool (Scuff, times (number of repetitions)) was an evaluation of wear resistance using Scuff instrument. The wear resistance was measured based on the number of repetitions in which an upper surface of a functional layer of a window is peeled off when the window surface is rubbed by repeatedly moving the steel wool at 60 mm/min and 45 revolutions per minute (rpm) with a load of 1.5 kilograms (kg) applied to the steel wool (Ribenon #0000).

Chemical resistance was evaluated based on changes in surface of the window upper surface after providing ethanol before and after a wear test.

TABLE 2

| Item | Comparative Example | Example |
|---|---|---|
| Light transmittance (%) | 91 | 91 |
| Reflectance (%) | 6.6 | 6.6 |
| Haze (%) | 0.45 | 0.45 |
| Yellow Index | 0.20 | 0.20 |
| Crack strain (%) | ≥5.0 | ≥5.0 |
| Indentation hardness (Hv) | ≤45 | ≥55 |
| Pencil hardness (H) | 2 | 4 |
| Impact resistance (cm) | 4 | 6 |
| Steel wool (Scuff, times) | 10 | 30 |
| Chemical resistance | Pass | Pass |

Referring to the results of Table 2, the window of Example exhibited similar levels of light transmittance, reflectance, haze, and yellow index to the window of Comparative Example. That is, it is seen that the window of Example exhibits excellent optical property level similar to the optical property level of Comparative Example. It is confirmed that the window of Example exhibits excellent mechanical properties compare to the window of Comparative Example. The window of Example has higher indentation hardness and pencil hardness than the window of Comparative Example, and thus, it is seen that Example exhibits higher mechanical properties of surface hardness than Comparative Example. In addition, it is confirmed that the window of Example has a satisfactory level of flexibility similar to the flexibility of Comparative Example given the similar crack strain values.

In addition, in the pen drop test, the window of Example showed a higher height, and accordingly, it is seen that the window of Example exhibits improved impact resistance compared to the window of Comparative Example. It is seen that the window of Example also exhibits excellent characteristics in the wear resistance evaluation of surface strength and durability compared to Comparative Example, and for the chemical resistance, Example exhibits a similar level to Comparative Example.

That is, it is seen that the window of an embodiment exhibits excellent optical properties, satisfactory flexibility, excellent characteristics in impact resistance, wear resistance, surface hardness, and the like.

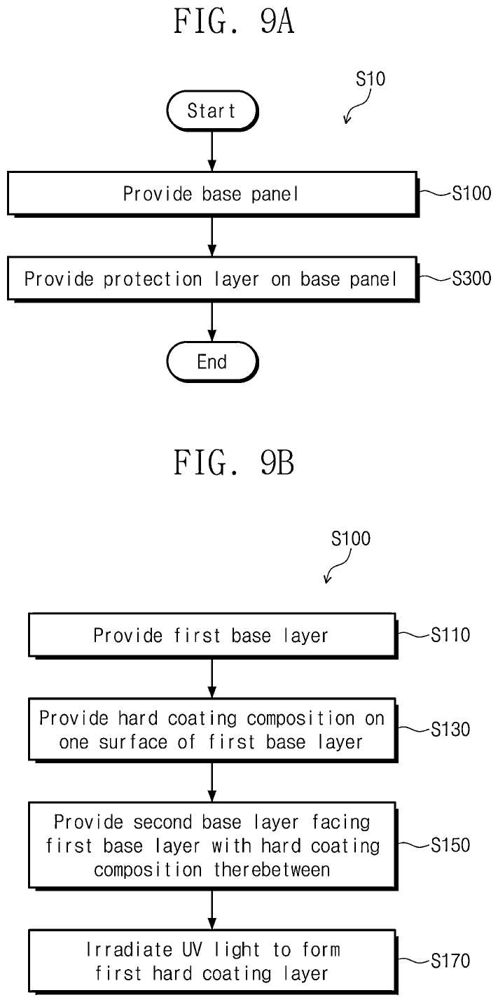

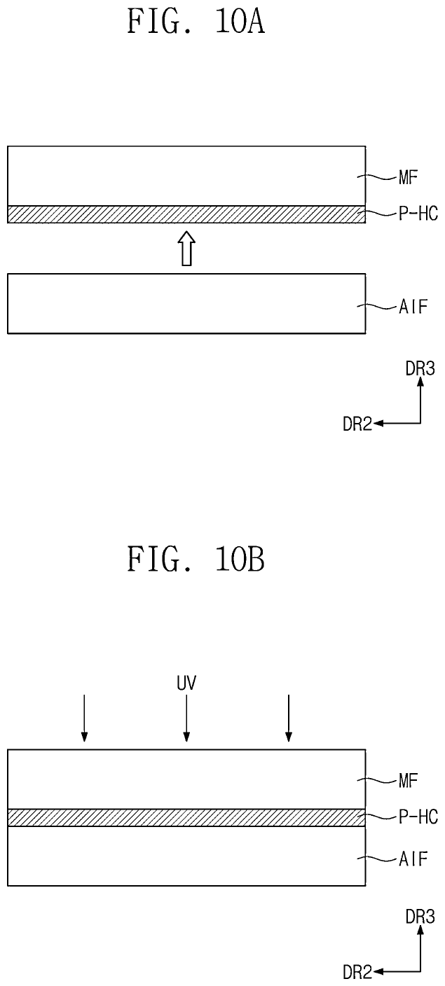

Hereinafter, a method for manufacturing a window of an embodiment will be described with reference to FIGS. 9A to 10B and the like. In the description of the window manufacturing method of an embodiment, duplicated descriptions as those described with reference to FIGS. 1 to 8B above will not be described again, and different features will be mainly described.

FIG. 9A is a flowchart illustrating a method for manufacturing a window according to an embodiment. FIG. 9B is a flowchart illustrating a process in a method for manufacturing a window of an embodiment. FIGS. 10A and 10B each are a view schematically illustrating a process in a method for manufacturing a window of an embodiment.

The window manufacturing method (S10) of an embodiment may include providing a base panel (S100) and providing a protection layer on the base panel (S300). The providing of the base panel (S100) may include providing a first base layer (S110), providing a hard coating composition on one surface of the first base layer (S130), providing a second base layer facing the first base layer with the hard coating composition therebetween (S150), and providing ultraviolet (“UV”) light to form a first hard coating layer (S170).

FIG. 10A may show the providing of a second base layer facing the first base layer with the hard coating composition therebetween (S150) after the providing of a hard coating composition on one surface of the first base layer (S130). FIG. 10B may show the providing of UV light to form a first hard coating layer (S170).

In the window manufacturing method of an embodiment, the provided first base layer MF may be a polymer film including polyimide, polyethylene terephthalate, polyacrylate, polymethyl methacrylate, polycarbonate, or polyethylene naphthalate. The first base layer MF may have a thickness of about 30 μm to about 100 μm.

The hard coating composition P-HC may be provided on one surface of the first base layer MF. The hard coating composition P-HC may contain an acrylic compound, an epoxy-based compound, a siloxane-based compound, or a urethane-based compound.

The providing of the hard coating composition on one surface of the first base layer (S130) may be a process of applying the hard coating composition to the first base layer MF. The coating method of the hard coating composition is not particularly limited, and multiple commonly known coating methods may be used. For example, various methods such as spin coating, dip coating, spray coating, slit coating, roll to roll coating, etc. may be used, and the embodiment is not limited thereto.

Before curing the provided hard coating composition, the second base layer AIF may be provided to face the first base layer MF. The second base layer AIF may be disposed to face the first base layer MF with the hard coating composition P-HC therebetween. The hard coating composition P-HC may be provided directly between the first base layer MF and the second base layer AIF.

The second base layer AIF provided in the window manufacturing method of an embodiment may include polyimide (PI), polyamide (PA), polyethylene terephthalate (PET), polyacrylate, polymethyl methacrylate (PMMA), polycarbonate (PC), polyethylene naphthalate (PEN), polyurethane (PU), polydimethylsiloxane (PDMS), or rubber. The second base layer AIF may have a thickness of about 30 μm to about 200 μm.

The providing of UV light to form a first hard coating layer (S170) may be a process of providing ultraviolet (“UV”) light to the hard coating composition P-HC provided between the first base layer MF and the second base layer AIF to form a hard coating layer through polymerization and curing reaction.

The providing of UV light to form a first hard coating layer (S170) may be a process of irradiating the first base layer MF, the hard coating composition P-HC, and the second base layer AIF, which are stacked, with UV to form the first hard coating layer HC-B (FIG. 6). That is, UV light irradiation is applied to pass through the first base layer MF or the second base layer AIF, which has high light transmittance, to cure the hard coating composition P-HC. Accordingly, a separate member or a separate process for bonding the first base layer MF and the second base layer AIF may be skipped, and the process of the window manufacturing method is simplified, thereby increasing process productivity in the window manufacturing method of an embodiment.

In addition, the irradiation intensity and irradiation amount of UV light provided in the forming of the first hard coating layer using UV light (S170) may be adjusted to control the level of curing of the hard coating layer. Accordingly, the bonding strength and hardness of the first hard coating layer HC-B (FIG. 6) may be easily controlled.

Although not shown, the method for manufacturing a window according to an embodiment further includes: providing a hard coating composition on the first base layer, and providing UV light to the provided hard coating composition to form a second hard coating layer HC-U, and may thus be used in the manufacturing of a window having the base panel structure of an embodiment shown in FIG. 7A.

In addition, the window manufacturing method of an embodiment includes providing a hard coating composition on the first base layer, providing a third base layer above the first base layer with the provided hard coating composition therebetween, and irradiating the first base layer, the hard coating composition, and the third base layer, which are stacked, using UV light to form a second hard coating layer, and may thus be used in the manufacturing of a window having the base panel structure of an embodiment shown in FIG. 7B. The second hard coating layer HC-U (FIG. 7B) may be used as a bonding layer for bonding the first base layer MF (FIG. 7B) and the third base layer AIF-U. That is, UV light irradiation is applied to pass through the first base layer MF or the third base layer AIF-U, which has high light transmittance, to cure the hard coating composition P-HC. Accordingly, a separate member or a separate process for bonding the first base layer MF and the third base layer AIF-U may be skipped, and the process of the window manufacturing method is simplified, thereby effectively increasing process productivity in the window manufacturing method of an embodiment.

A window of an embodiment includes a plurality of base layers formed of or include a polymer material or an organic material having flexibility, and at least one hard coating layer to obtain flexibility used in a flexible electronic device and to exhibit impact resistance and excellent surface hardness for protecting a display module disposed below. An electronic device of an embodiment includes a window of an embodiment on a display module, and may thus minimize the buckling of the window despite repetitive folding operation in use, and exhibit excellent durability.

In addition, a method for manufacturing a window of an embodiment includes providing a hard coating composition between base layers and then applying irradiation of UV light to form a hard coating layer, and may thus exhibit effectively improved process productivity.

A window of an embodiment further includes an additional base layer in addition to a main base layer, and includes a hard coating layer, and may thus exhibit both satisfactory folding characteristics and excellent mechanical properties.

An electronic device of an embodiment includes a window disposed on a display module and including two or more base layers and hard coating layers, and may thus exhibit satisfactory folding characteristics and excellent impact resistance characteristics.

A method for manufacturing a window according to an embodiment includes providing a hard coating composition between two base layers and then applying irradiation of UV light to form a hard coating layer, and may thus simplify window manufacturing processes.

Although the present invention has been described with reference to a preferred embodiment of the present invention, it will be understood that the present invention should not be limited to these preferred embodiments but various changes and modifications can be made by those skilled in the art without departing from the spirit and scope of the present invention.

Accordingly, the technical scope of the present invention is not intended to be limited to the contents set forth in the detailed description of the specification, but is intended to be defined by the appended claims.

What is claimed is:

1. A window comprising:
a base panel; and
a protection layer disposed above the base panel,
wherein the base panel includes:
a first base layer;
a second base layer disposed below the first base layer; and
a first hard coating layer disposed between the first base layer and the second base layer, and
the protection layer includes:
a base film disposed above the first base layer; and
a functional layer disposed above the base film and containing a hard coating agent.

2. The window of claim 1, having a light transmittance of 90 percentages (%) or more and a haze of 1% or less in a visible light range.

3. The window of claim 1, wherein the first base layer is a polymer film containing polyimide, polyamide, polyethylene terephthalate, polycarbonate, or polyethylene naphthalate.

4. The window of claim 1, wherein the first base layer has a thickness of about 30 micrometers (μm) to about 100 μm.

5. The window of claim 1, wherein the second base layer contains polyimide, polyamide, polyethylene terephthalate, polyacrylate, polymethyl methacrylate, polycarbonate, polyethylene naphthalate, polyurethane, polydimethylsiloxane, or rubber.

6. The window of claim 1, wherein the second base layer has a thickness of about 30 μm to about 200 μm.

7. The window of claim 1, wherein the base panel further comprises a second hard coating layer disposed above the first base layer.

8. The window of claim 7, wherein the first hard coating layer and the second hard coating layer each independently have a thickness of about 5 μm or to about 25 μm.

9. The window of claim 7, wherein the first hard coating layer and the second hard coating layer each independently contain an acrylic compound, an epoxy-based compound, a siloxane-based compound, or a urethane-based compound.

10. The window of claim 7, wherein the base panel further comprises a third base layer disposed above the second hard coating layer, and the third base layer contains polyimide, polyamide, polyethylene terephthalate, polyacrylate, polymethyl methacrylate, polycarbonate, polyethylene naphthalate, polyurethane, polydimethylsiloxane, or rubber.

11. The window of claim 10, wherein the third base layer has a thickness of about 30 μm to about 200 μm.

12. The window of claim 1, wherein the first hard coating layer is directly disposed between the first base layer and the second base layer.

13. The window of claim 1, wherein the functional layer further comprises an anti-fingerprint coating agent, and is a single layer.

14. The window of claim 1, wherein the functional layer comprises a first sub-functional layer including the hard coating agent, and a second sub-functional layer disposed above the first sub-functional layer and including an anti-fingerprint coating agent.

15. The window of claim 1, wherein the protection layer further comprises a third hard coating layer disposed between the base panel and the base film.

16. The window of claim 1, further comprising a window adhesive layer disposed between the base panel and the protection layer.

17. An electronic device comprising:
a display module; and
a window disposed above the display module and including a base panel and a protection layer disposed above the base panel,
wherein the base panel includes:
a first base layer;
a second base layer disposed below the first base layer; and
a first hard coating layer disposed between the first base layer and the second base layer, and
the protection layer includes:
a base film disposed above the first base layer; and
a functional layer disposed above the base film and containing a hard coating agent.

18. The electronic device of claim 17, wherein the electronic device is divided into a folding area which is folded with respect to a folding axis extending in one direction and a non-folding area adjacent to the folding area.

19. The electronic device of claim 17, wherein the first base layer is a polymer film containing polyimide, polyamide, polyethylene terephthalate, polyacrylate, polymethyl methacrylate, polycarbonate, or polyethylene naphthalate, and has a thickness of about 30 μm to about 100 μm.

20. The electronic device of claim 17, wherein the second base layer contains polyimide, polyamide, polyethylene terephthalate, polyacrylate, polymethyl methacrylate, polycarbonate, polyethylene naphthalate, polyurethane, polydimethylsiloxane, or rubber, and has a thickness of about 30 μm to about 200 μm.

21. The electronic device of claim 17, wherein the base panel further comprises a second hard coating layer disposed above the first base layer.

22. The electronic device of claim 21, wherein the first hard coating layer and the second hard coating layer each independently contain an acrylic compound, an epoxy-based compound, a siloxane-based compound, or a urethane-based compound, and each independently have a thickness of about 5 μm or to about 25 μm.

23. The electronic device of claim 17, wherein the functional layer is an uppermost layer, and further comprises an anti-fingerprint coating agent.

24. A method for manufacturing a window, the method comprising:
providing a base panel; and
providing a protection layer on the base panel,
wherein the providing of the base panel includes:
providing a first base layer;
providing a hard coating composition on one surface of the first base layer;
providing a second base layer facing the first base layer with the provided hard coating composition therebetween; and
irradiating the first base layer, the hard coating composition, and the second base layer, which are stacked, with ultraviolet (UV) light to form a first hard coating layer.

25. The method of claim 24, wherein the hard coating composition contains an acrylic compound, an epoxy-based compound, a siloxane-based compound, or a urethane-based compound.

26. The method of claim 24, wherein the first base layer is a polymer film containing polyimide, polyamide, polyethylene terephthalate, polyacrylate, polymethyl methacrylate, polycarbonate, or polyethylene naphthalate, and has a thickness of about 30 μm to about 100 μm.

27. The method of claim 24, wherein the second base layer contains polyimide, polyamide, polyethylene terephthalate, polyacrylate, polymethyl methacrylate, polycarbonate, polyethylene naphthalate, polyurethane, polydimethylsiloxane, or rubber, and has a thickness of about 30 μm to about 200 μm.
